(19) United States
(12) Patent Application Publication
(10) Pub. No.: US 2024/0116714 A1
(43) Pub. Date: Apr. 11, 2024

(54) VERTICAL TRAY STORAGE SYSTEM WITH INTERNAL ELECTRICAL POWER DISTRIBUTION SYSTEM

(71) Applicant: Vidir Solutions Inc., Arborg (CA)

(72) Inventors: Dimitri Warlet Caldeira, Arborg (CA); Delmer Plett, Arborg (CA); Umair Younas, Arborg (CA); Younus Dewan, Arborg (CA)

(21) Appl. No.: 18/452,000

(22) Filed: Aug. 18, 2023

Related U.S. Application Data
(60) Provisional application No. 63/414,061, filed on Oct. 7, 2022.

(51) Int. Cl. B65G 1/137

(52) U.S. Cl. CPC B65G 1/1373

(57) ABSTRACT

A system for storing items comprises a rack with upstanding posts delimiting a vertically extending storage space with individual storage locations formed by generally horizontally-oriented members supported on the posts. The system includes trays respectively removably received at the individual storage locations. The system further includes an elevator configured for moving the trays between the storage locations and a user-retrieval space adjacent a bottom of the rack. The system features an electrical power distribution system to deliver electrical power from a source to items on the trays, which includes distribution ports supported on the rack and respectively associated with the individual storage locations, receiver ports carried on the trays and configured for removably electrically connecting with the distribution ports, and electrical receptacles electrically connected to the receiver ports and configured to connect to electrical loads. A rack power transfer controller is configured to control the distribution ports to transfer electrical power to a respective one of the trays when the tray is in the storage condition.

This application claims the benefit under 35 U.S.C. 119(e) of U.S. provisional application Ser. No. 63/414,061 filed Oct. 7, 2022.

### FIELD OF THE INVENTION

The present invention relates generally to a vertical tray storage system for storing items, and more particularly to such a system with an internal electrical power distribution system for providing electrical power for electrical devices carried on replaceable trays.

### BACKGROUND

The Applicant commercially offers a vertical storage system, referred to in industry as a vertical lift module, which has a storage rack with a plurality of vertical storage locations defined by pairs of horizontally opposite rails; removable trays removably supported on the pairs of rails; and an elevator in communication with the storage rack and having a platform for retrieving trays and presenting them to a retrieval space below the storage locations. It may be desirable to supply electrical power to the removable trays of such a system to increase flexibility of the types of items which can be stored.

### SUMMARY OF THE INVENTION

According to an aspect of the invention there is provided a system for storing items comprising:
a storage rack having:
   a plurality of upstanding posts arranged in spaced relation to each other and for resting on a support surface, wherein the posts delimit an upwardly-extending storage space for containing the items during storage; and
   a plurality of generally horizontally-oriented members supported on the posts at vertically spaced positions thereon and forming a plurality of respective storage locations arranged one above another in the storage space;
a plurality of trays respectively removably received at the storage locations of the storage rack in respective storage conditions of the trays, wherein each tray comprises:
   a base having a generally-horizontal upwardly-facing support surface for receiving items to be stored, wherein the base has a front and a longitudinally opposite rear and laterally opposite sides; and
   a peripheral upstanding sidewall connected to the base and extending along at least one of the front, the rear and the sides of the base;
an elevator configured for moving the trays between the storage locations and a retrieval space adjacent a bottom of the storage rack for user retrieval of one or more selected ones of the items, wherein the elevator comprises a platform supported for upward and downward movement relative to the storage rack and configured to carry the trays and exchange the trays with the storage rack; and
an electrical power distribution system for providing electrical power for the items on the trays, wherein the electrical power distribution system comprises:
   a plurality of distribution ports supported by the storage rack and respectively associated with the storage locations, wherein the distribution ports are arranged for electrical connection to an electrical power source and configured to transmit the electrical power therefrom;
   a plurality of receiver ports distinct from the distribution ports and respectively supported on the trays, wherein each of the receiver ports is configured to removably electrically connect to a respective one of the distribution ports to receive the electrical power from the electrical power source when the respective tray is stored at a corresponding one of the storage locations with which the respective distribution port is associated;
   a plurality of electrical receptacles supported on the trays and electrically connected to the receiver ports to receive the electrical power therefrom, wherein the electrical receptacles are configured to be electrically connected to electrically-powered types of the items on the trays; and
   a rack power transfer controller operatively communicated with the distribution ports and the receiver ports, wherein the power transfer controller is configured to control the distribution ports to transfer the electrical power to the receiver ports when respective ones of the trays are in the storage condition.

This arrangement supplies electrical power to individual trays when stored in the rack.

In one arrangement, the distribution and receiver ports are configured for electrical interconnection by mechanically biasing electrical conductors of the distribution and receiver ports into physical contact.

In one arrangement, the electrical power distribution system includes a plurality of tray power transfer controllers respectively operatively communicated with the receiver ports supported on the trays, wherein the tray power transfer controllers are operatively communicated with the rack power transfer controller and configured to respectively control the receiver ports to receive the electrical power from the distribution ports, and wherein the tray power transfer controllers are configured to block transmission of the electrical power to the electrical receptacles until a prescribed duration has elapsed.

### BRIEF DESCRIPTION OF THE DRAWINGS

The invention will now be described in conjunction with the accompanying drawings in which:

FIG. 1 schematically shows an interior side view of an arrangement of system for storing items according to the present invention;

FIG. 2 schematically shows a partial interior top plan view of the arrangement of FIG. 1, in which the tray is shown as received in one of the storage locations;

FIG. 3 schematically shows a partial interior side view of the arrangement of FIG. 1, in which the elevator is in a raised position relative to a user-retrieval position shown in FIG. 1;

FIG. 4 is an exploded view of a tray and a portion of rack of the arrangement of FIG. 1; and

FIG. 5 is a schematic diagram of control circuitry of the arrangement of FIG. 1.

In the drawings like characters of reference indicate corresponding parts in the different figures.

### DETAILED DESCRIPTION

The accompanying figures show a system 10 for storing items, that is a storage system, generally comprising a storage rack 12 defining a plurality of storage locations 14 arranged one above the other; a plurality of trays 16 removably stored at the storage locations 14 of the rack 12 in respective storage conditions of the trays; and an elevator 18 configured for moving a selected one of the trays between an assigned one of the storage locations 14 and a retrieval space 20 adjacent a bottom of the storage rack, which is at or in proximity to a support surface SS to be accessible by a user.

More specifically, the storage rack 12 comprises a plurality of upstanding posts 23 arranged in spaced relation to each other, generally in longitudinal and lateral directions across the support surface SS, and for resting on the support surface. The posts 23 delimit an upwardly-extending storage space 25 for containing the items during storage. Basically, the posts 23 define a frame of the storage rack. The frame may include horizontal cross-members 28 extending longitudinally or laterally between respective ones of adjacent pairs of the posts 23 to brace the frame. Laterally-extending ones of the cross members 28 are located at a longitudinal rear of the frame so as not to obstruct access to the storage space 25 from a longitudinal front where the elevator 18 traverses the rack. Bottoms 23A of the posts 23 proximal to the support surface SS may be interconnected to form a base 30 defining the bottom of the rack.

The rack 12 includes a plurality of generally horizontally-oriented members 33 supported on the posts 23 at vertically spaced positions thereon and forming a plurality of respective storage locations 14 arranged one above another in the storage space 25. For example, the members 33 are in the form of rails and are arranged in pairs in which respective ones of the rails are horizontally-opposite one another and laterally spaced-apart. Thus, the rails extend longitudinally of the frame from a front, where the trays enter the storage space, to a rear, which is generally inaccessible for retrieving the trays in the storage space. In the illustrated arrangement, the rails are U-shaped channels which open upwardly to slidingly receive laterally opposite sides of the tray configured for mating sliding engagement with the rails.

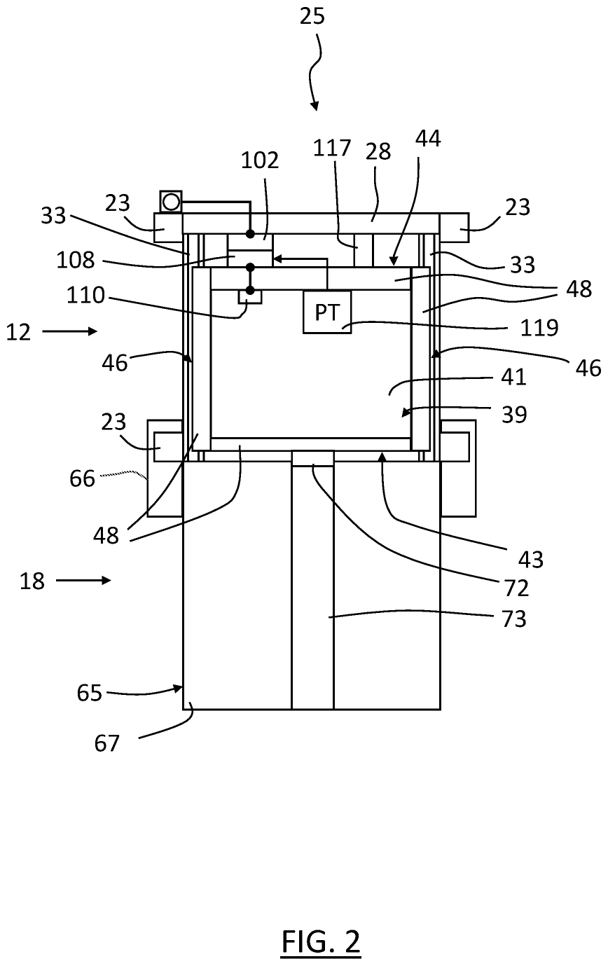

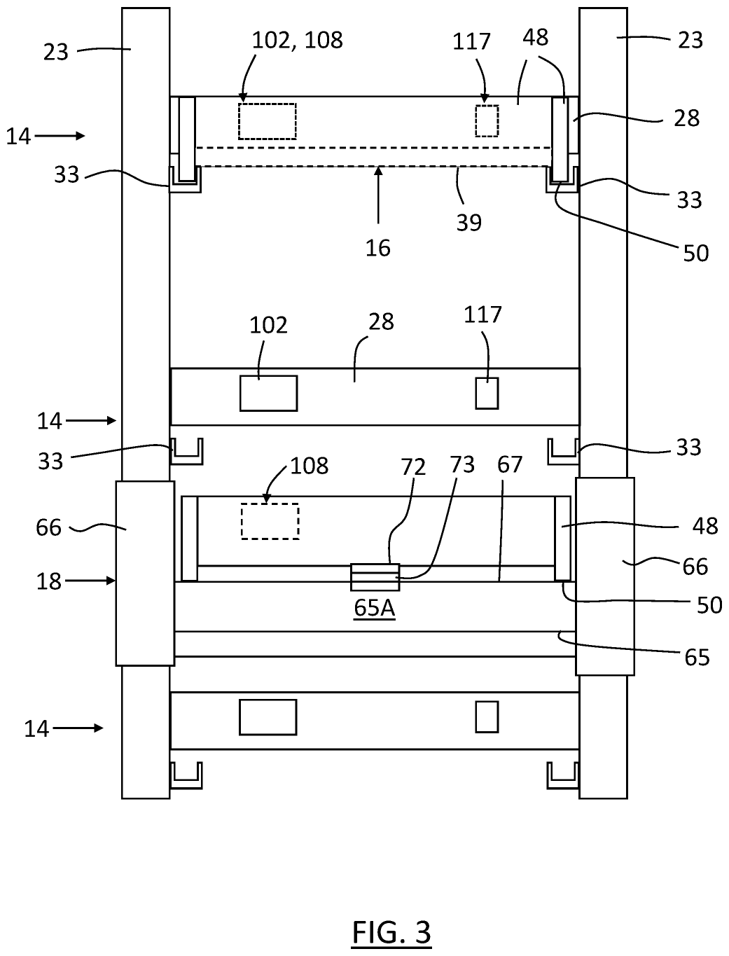

With reference to FIGS. 2 and 3, and turning now to the trays 16 which are respectively removably received at the respective storage locations 14 of the storage rack 12, each tray 16 comprises a base 39 having a generally-horizontal upwardly-facing support surface 41 for receiving items to be stored, a front 43 and a longitudinally opposite rear 44, and laterally opposite sides 46. Furthermore, each tray 16 includes a peripheral upstanding sidewall 48 connected to the base 39 and extending along at least one of the front, the rear and the sides of the base 39. The base of the tray acts as a floor thereof, and the peripheral wall acts as a retention element to resist stored items from falling off the tray.

In the illustrated arrangement, the tray base 39 is planar and the peripheral sidewall 48 stand upwardly therefrom substantially at right angles to the plane defined by the base 39. Preferably, the peripheral sidewall 48 has longitudinally opposite portions at the front 43 and rear 44 and laterally opposite portions at the sides 46 of the tray to define a container over the upper surface 41 of the base 39.

Also in the illustrated arrangement, the laterally opposite portions of the sidewall 48 extend below the base 39 of the tray to lowered bottoms 50 (relative to an underside of the base 39) to form support rails 50 for slidably mating with the channel-shaped storage rails of the rack.

The elevator 18 configured for moving the trays 16 between the storage locations 14 and the retrieval space 20 for user-retrieval of one or more selected items comprises a platform 65 supported for upward and downward movement relative to the storage rack and configured to carry the trays 16. In the illustrated arrangement, the platform 65 is operatively coupled to the posts 23 of the rack 12 at the longitudinal front thereof and configured to traverse the posts, which define a generally vertical path of movement for the platform. For example, the platform 65 is configured to traverse the posts by rollable traction elements in rolling engagement with opposite front and rear surfaces of the posts, which elements are received in sleeves 66 attached to the platform and forming vertically extending thru-passageways in which the posts are matably received. The sleeves are provided in a pair at laterally opposite sides of the platform to receive a frontal pair of the posts of the rack 12. The elevator platform 65 defines an upwardly-facing surface 67 configured to receive a respective one of the trays 16, which surface is substantially planar and horizontal.

In the illustrated arrangement, the platform 65 also includes a transfer assembly 70 (schematically shown) on an upper side thereof, adjacent the surface 67, such that the platform is configured for exchanging a respective one of the trays with the rack 12, whether the assigned storage location 14 or the retrieval space 20. The transfer assembly 70 is configured to removably secure to a respective one of the trays and to displace the same relative to the platform 65 which generally remains in fixed horizontal location. More specifically, the transfer assembly 70 is configured for displacing a tray in a longitudinal direction relative to the platform 65 and the rack 12. For example, as in the illustrated arrangement, the transfer assembly 70 includes a carrier 72 disposed above the upper surface 67 configured to removably attach to a tray by its base 39. The carrier 72 is movably supported on an endless drive member such as a chain with an upper run 73 extending longitudinally of the platform between longitudinally opposite front 75 and rear 76 thereof. The endless drive member is rotatably supported by a main body 65A of the platform 65, which defines the upper surface 67, and is driven for rotation relative to the main body to displace the carrier longitudinally of the platform.

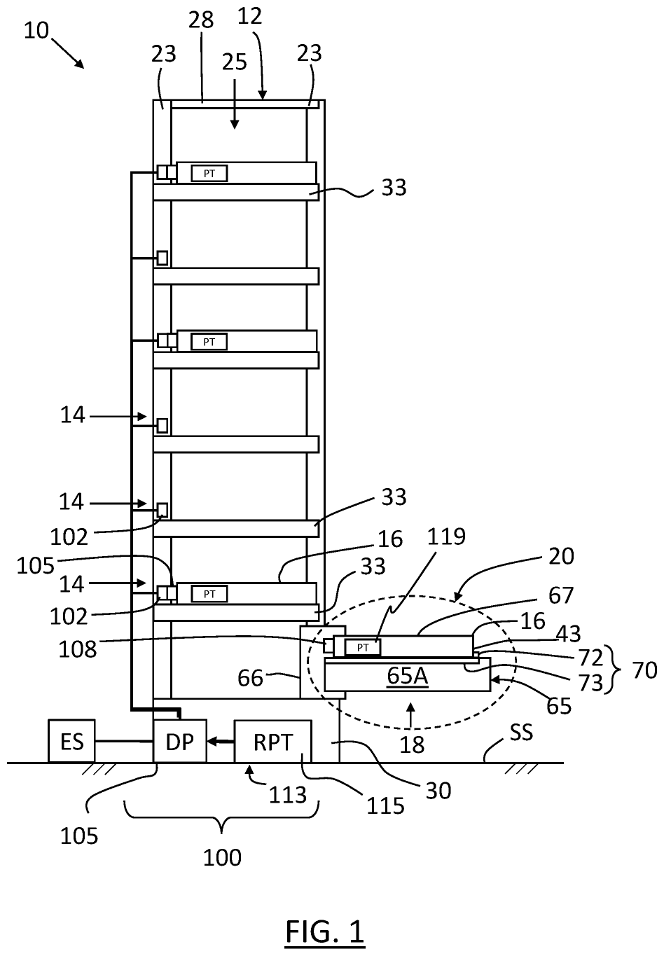

Particularly referring to FIGS. 1 and 3, to deliver electrical power to items stored in the rack 12 on the trays, the storage system 10 comprises an electrical power distribution system 100. The electrical power distribution system 100 comprises a plurality of distribution ports 102 supported by the storage rack 12 and respectively associated with the storage locations 14, typically by being respectively physically located at or adjacent the respective storage locations. The distribution ports 102 are arranged for electrical connection to an electrical power source ES and configured to transmit or transfer the electrical power therefrom. Typically, the electrical power source ES is external to the storage system, for example, a mains power (which typically is AC). In the illustrated arrangement, the power source is external, and the distribution ports 102 are operatively electrically connected to the external source by a distribution panel 105 of the distribution system. The distribution panel 105 is intermediate and electrically in series with the external source ES and the distribution ports 102 relative to a flow of electricity. Thus, a single electrical connection from the storage system 10, via the distribution panel 105, is provided to the external electrical source ES.

The distribution panel 105 includes a connection terminal for electrically connecting to the electrical source ES. The distribution panel 105 may also include a transformer stage electrically connected in series with the connection terminal and each of the distribution ports 102 which are electrically connected in parallel with each other. Typically, the transformer stage is configured to reduce or step-down the voltage from the source ES to a level or value at which consumer or commercial electrical devices typically operate.

Typically, as more clearly shown in FIGS. 2 and 3, the distribution ports 102 are mounted in fixed relation to the rack 12 at spaced heights to be registered with the respective storage locations 14. Generally speaking, a single distribution port is provided for each storage location. In the illustrated arrangement, the distribution ports 102 are mechanically supported on the horizontal laterally-extending cross members 28 registered with the storage locations 14, as more clearly shown in FIGS. 2 and 3. Typically, each such cross-member 28 is supported above and in proximal relation to the rails 33 of the corresponding storage location 14, so as to be closer to same as compared to an upper set of the rails forming an adjacent upper one of the storage locations.

The power distribution system 100 further comprises a plurality of receiver ports 108 distinct from the distribution ports 102 and respectively supported on the trays 16. Thus, the receiver ports 108 are physically separable from the distribution ports. Each receiver port 108 is configured to removably electrically connect to a respective distribution port 102 to receive the electrical power from the electrical power source ES when the respective tray 16 is stored at a corresponding one of the storage locations 14 with which the respective distribution port 102 is associated.

In the illustrated arrangement, the distribution and receiver ports 102, 108 are configured for electrical interconnection by mechanical biasing electrical conductors of the ports into physical or mechanical contact. More specifically, each of the distribution and receiver ports 102, 108 comprises an electrically conductive plate supported on a mounting base, which is attached to the corresponding one of the tray or the rack, by an interconnecting biasing element. The biasing element is configured to urge the electrically conductive plate away from the mounting base in a perpendicular direction to planes of the plate and base. This perpendicular direction is oriented to be parallel to the direction of movement of the respective tray into or out of the rack. The biasing element may be, for example, a compression spring. Furthermore, when electrical connection is established between a pair of the distribution and receiver ports, there may be provided a latch in operative association with one of the pair of distribution and receiver ports at a given storage location for securing the respective tray in fixed relation to the rack. For example, the distribution and receiver ports of the type typically used for charging plug-in battery electric land vehicles, which may be referred to in industry as AGV and AMR charging stations.

For removably electrical coupling, the distribution port 102 of the respective storage location 14 and the receiver port 108 of the respective tray 16 stored thereat are aligned in the longitudinal and lateral directions relative to the rack 12 for electrical interconnection when the tray is received in a storage or stowed condition relative to the rack, in which it is stationary, supported along its full depth between front 43 and rear 44 by the horizontal support member 33, free from support by the elevator platform 65 or elevator more generally, and received in the storage space 25 of the rack. Thus, by mere placement of the tray at the assigned storage location, the tray is electrically connected via the receiver port 108 to the rack's electrical system via the corresponding distribution port 102.

As more clearly shown in FIGS. 2 and 3, to supply the power from the power source ES to the items on the trays 16, the distribution system 100 includes a plurality of electrical receptacles 110 supported on the trays 16 and electrically connected to the receiver ports to receive the electrical power therefrom, that is the electrical power delivered to the receiver ports and supplied from the source. The electrical receptacles 110 are configured to be electrically connected to electrically-powered types of the items on the trays. It will be appreciated that the receptacles 110 are generally provided for access from an interior of the tray, that is from its storage volume arranged for receiving items to be stored on the tray, while the receiver ports are external to this storage volume.

Moreover, and referring to FIG. 1, the distribution system includes a rack power transfer controller (PTC) 113 operatively communicated with the distribution ports 102 and the receiver ports 108, for example by wired communication by low voltage wiring distinct from power cables carrying electrical power from the source ES. The rack power transfer controller 113 is configured to control the distribution ports 102 to transfer the electrical power to the receiver ports 108 when respective trays 16 are in the storage condition.

In the illustrated arrangement, the rack PTC 113 comprises a main controller unit 115 including a processor and a non-transitory memory storing executable instructions thereon to perform the various functions of the rack PTC, and a plurality of limit switches 117 operatively communicated with the main controller 115 and respectively associated with the storage locations 14 for engaging the trays received thereat. Thus, each limit switch 117 is configured to detect one of the trays received at the associated storage location by physical or mechanical engagement with the tray. The limit switches 117 are distinct from the distribution ports 102 and supported on the same set of cross-members 28 at the rears of the storage locations, such that the limits switches are arranged to engage the rears of the trays, either the base or the peripheral wall of the respective tray (the latter being the case in the illustrated arrangement). The limit switches may be supported proud of the distribution ports 102 which engage the receiver ports, that is with their contact surface located in leading relation to the distribution ports, so as to be presented at positions suitable for contact by the trays when the tray is electrically connected to the rack via combination of ports 102, 108. When the limit switch associated with one of the storage locations is engaged, meaning that one of the trays is received thereat, this acts to close a respective power delivery circuit for that storage location so that power is transferred from the source to the distribution port of the associated storage location.

In the illustrated arrangement, the electrical power distribution system 100 further includes a plurality of tray power transfer controllers (PTCs) 119 respectively operatively communicated with the receiver ports 108 supported on the trays 16, for example by wired communication therewith. The tray power transfer controllers 119 are also operatively communicated with the rack PTC 113 and configured to respectively control the receiver ports 108 to receive the electrical power from the distribution ports 102, and the tray power transfer controllers 119 are configured to block transmission of the electrical power to the electrical receptacles 110 until a prescribed duration has elapsed. In the illustrated arrangement, there is a distinct one of the tray PTCs 119 carried on each of the trays 16 and in wired communication with the receiver ports 108 on the same tray.

In the illustrated arrangement, the respective tray PTC 119 is operatively communicated with the rack PTC 113 by a distinct transmitter 127, separate from the receiver port 102, which is operatively communicated with a distinct receiver 129, separate from the distribution port 102.

In the illustrated arrangement, each of the tray PTCs 119 comprises a timer switch 125, which is set to the prescribed duration, electrically connected in series between the receiver port 108 and the electrical receptacle 110 of a common tray. The timer switch 125 is electrically connected to a transmitter 127 configured to send a signal to a cooperating receiver 129 of the rack PTC 113 in an initial blocking position or state, during which the prescribed duration elapses, in which the power signal is blocked from transmission to the electrical receptacle, such as by a switch 132 electrically connected between the distribution panel 103 and a respective one of the distribution ports 102. It will be appreciated that there is provided a plurality of the switches 132, one for each tray location in the rack, so as to be associated with the same. In the initial blocking state, the tray PTC 119 acts to confirm to the rack PTC 113 that electrical power is available at the corresponding tray, that is at the receiver port 108 thereof. In the event that the rack PTC does not receive the confirmation signal from the tray that electrical power is available thereat, after receipt of the limit switch signal that the tray is physically present at the associated storage location, the rack PTC 113 is configured to deactivate the distribution port 102 at the associated storage location.

After the prescribed duration has elapsed, the timer switch 125 is automatically operated in a second delivery position or state, in which the electrical power is delivered to the receptacle 113.

In use, the storage system 10 delivers a tray to an assigned one of the storage locations 14. Usually this takes place after the tray was at the retrieval space 20, and thus the elevator 18 moves one of the trays from the retrieval space to an assigned storage location, whether determined by input from the user or automatically by the storage system 10 based on available, that is free or empty, storage locations.

The rack 12 comprises a plurality of fixed distribution ports 102 at locations 14 therein configured to receive the trays. The trays 16 include respective receiver ports 108 carried thereon for removably electrically connecting with the distribution ports.

When the tray is transferred from the elevator to the rack at the assigned storage location, and upon being received in the stowed position, in which the tray is in fixed position and location relative to the rack, the receiver port 108 of the tray is electrically mated with the distribution port 102 of the assigned storage location, and electrical power transfer to the tray can begin. In the stowed position (i) the tray is stationary, that is not moving; and (ii) the receiver port 108 is electrically connected to the distribution port 102.

Electrical power transfer from the rack 12, which is received from the source ES, and to tray 16 optionally comprises the steps of:
At a respective one of the storage locations 14 where a distribution port is provided, confirming presence of a tray thereat—upon confirmation thereof, the system presumes that the tray is in the storage position suited for receiving electrical power;
Supplying electrical power to the distribution port of the storage location where tray presence has been confirmed; and
Delaying electrical interconnection of an onboard tray receptacle, configured to deliver the electrical power to an electrical device on the tray, with the receiver port electrically connected to the distribution port.

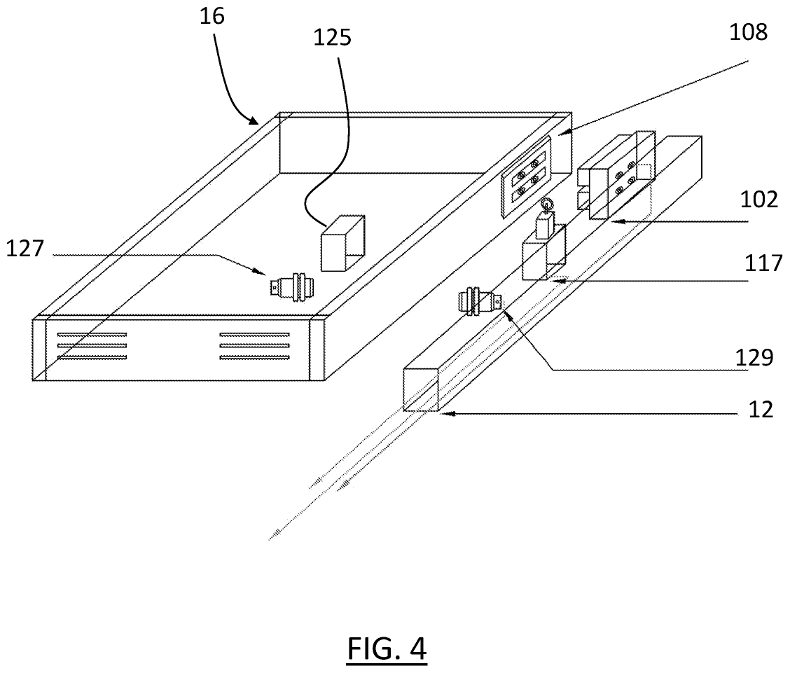

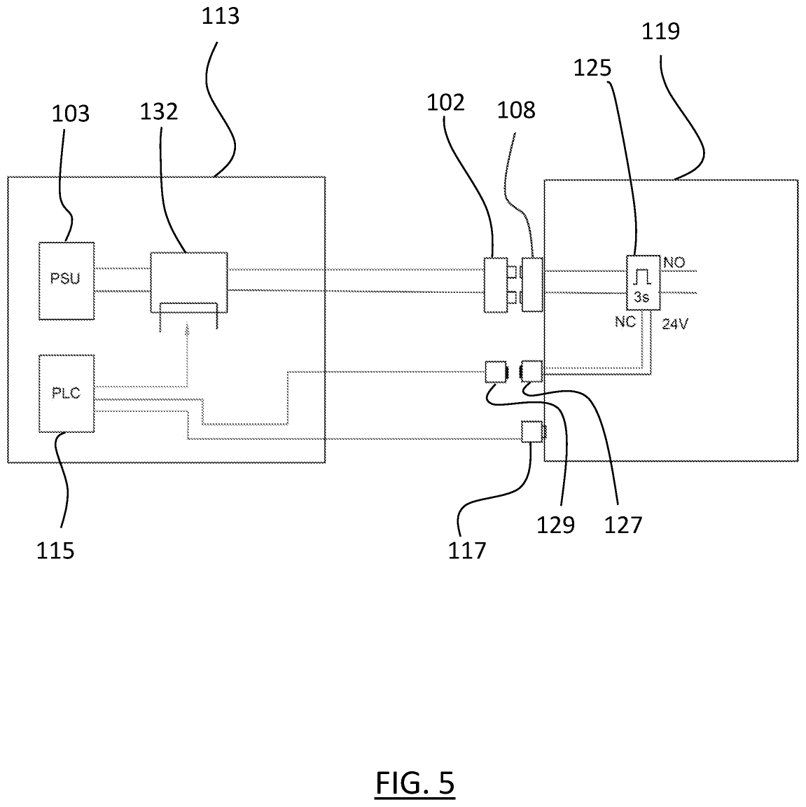

As more clearly shown in FIGS. 4 and 5, features of the tray include:
a) Power contacts
   Alternatively referred to as charging contacts, these are used to provide power to the tray. For example, the receiver port of the tray may be referred to as a base plate, and the distribution port on the rack may be referred to as a collector and electrical contacts thereof may be of copper material.
   When the voltage for appliances or items/articles carried by the tray is prescribed at 24 V DC, the power contacts are rated for, for example, 60 V DC and an electrical current of 50 A; the relatively low 24V DC is considered a safe voltage with minimum electrical shock and arc flash hazard.
b) Limit switch:
   Provides physical confirmation of the tray being stored at a specific location with no power
   Once the tray is stored and the limit switch is engaged, a programmable logic controller (PLC) of a control circuit sends a signal to activate the power contactor of the rack
   The prescribed voltage, in this case 24V DC, reaches the power contacts through a distribution wire or cable in the rack and activates a timer inside the tray.
c) Timer
   Provides a safe delay before powering up the stored tray to avoid electrical arcing
   A transmitter and receiver connected to the timer send a power confirmation signal to the PLC
d) Transmitter and receiver
   Provide power confirmation signal into the tray's transmitter; sends signal for 3 second to the receiver upon receiving power (+24 VDC) through normally closed (NC) terminals of the Timer
   Receiver send signal to the PLC which confirms PLC (i) Tray have been properly stored; (ii) Tray made firm contact with the Power Contacts; and (iii) Power is now available to be delivered safely into the Tray
   If in any case Receiver do not receive signal within the delay time after tray being stored. PLC program will de-activate the Power Contractor inside the rack.

The rack provides a mounting frame to locate relevant components thereof for engagement with corresponding components of the tray.

It will be appreciated that the rack includes a ventilation subsystem configured to dissipate heat generated by electrical power transfer and consumption in the storage system.

It will also be appreciated that in FIG. 5, the distribution panel 103 local to the system is alternatively referred to as PSU which stands for Power Switch Unit.

As described hereinbefore, the present invention relates to a system for storing items, which comprises a rack with upstanding posts delimiting a vertically extending storage space with individual storage locations formed by generally horizontally-oriented members supported on the posts. The system includes trays respectively removably received at the individual storage locations. The system further includes an elevator configured for moving the trays between the storage locations and a user-retrieval space adjacent a bottom of the rack. The system features an electrical power distribution system to deliver electrical power from a source to items on the trays, which includes distribution ports supported on the rack and respectively associated with the individual storage locations, receiver ports carried on the trays and configured for removably electrically connecting with the distribution ports, and electrical receptacles electrically connected to the receiver ports and configured to connect to electrical loads. A rack power transfer controller is configured to control the distribution ports to transfer electrical power to a respective one of the trays when the tray is in the storage condition.

The scope of the claims should not be limited by the preferred embodiments set forth in the examples but should be given the broadest interpretation consistent with the specification as a whole.

1. A system for storing items comprising:
a storage rack having:
a plurality of upstanding posts arranged in spaced relation to each other and for resting on a support surface, wherein the posts delimit an upwardly-extending storage space for containing the items during storage; and
a plurality of generally horizontally-oriented members supported on the posts at vertically spaced positions thereon and forming a plurality of respective storage locations arranged one above another in the storage space;
a plurality of trays respectively removably received at the storage locations of the storage rack in respective storage conditions of the trays, wherein each tray comprises:
a base having a generally-horizontal upwardly-facing support surface for receiving items to be stored, wherein the base has a front and a longitudinally opposite rear and laterally opposite sides; and
a peripheral upstanding sidewall connected to the base and extending along at least one of the front, the rear and the sides of the base;
an elevator configured for moving the trays between the storage locations and a retrieval space adjacent a bottom of the storage rack for user retrieval of one or more selected ones of the items, wherein the elevator comprises a platform supported for upward and downward movement relative to the storage rack and configured to carry the trays and exchange the trays with the storage rack; and
an electrical power distribution system for providing electrical power for the items on the trays, wherein the electrical power distribution system comprises:
a plurality of distribution ports supported by the storage rack and respectively associated with the storage locations, wherein the distribution ports are arranged for electrical connection to an electrical power source and configured to transmit the electrical power therefrom;
a plurality of receiver ports distinct from the distribution ports and respectively supported on the trays, wherein each of the receiver ports is configured to removably electrically connect to a respective one of the distribution ports to receive the electrical power from the electrical power source when the respective tray is stored at a corresponding one of the storage locations with which the respective distribution port is associated;
a plurality of electrical receptacles supported on the trays and electrically connected to the receiver ports to receive the electrical power therefrom, wherein the electrical receptacles are configured to be electrically connected to electrically-powered types of the items on the trays; and
a rack power transfer controller operatively communicated with the distribution ports and the receiver ports, wherein the power transfer controller is configured to control the distribution ports to transfer the electrical power to the receiver ports when respective ones of the trays are in the storage condition.

2. The storage system of claim 1 wherein the distribution and receiver ports are configured for electrical interconnection by mechanically biasing electrical conductors of the distribution and receiver ports into physical contact.

3. The storage system of claim 1 wherein the electrical power distribution system includes a plurality of tray power transfer controllers respectively operatively communicated with the receiver ports supported on the trays, wherein the tray power transfer controllers are operatively communicated with the rack power transfer controller and configured to respectively control the receiver ports to receive the electrical power from the distribution ports, and wherein the tray power transfer controllers are configured to block transmission of the electrical power to the electrical receptacles until a prescribed duration has elapsed.
